(19) United States
(12) Patent Application Publication
(10) Pub. No.: US 2017/0162621 A1
(43) Pub. Date: Jun. 8, 2017

(54) LIGHT CHANNELS WITH MULTI-STEP ETCH

(71) Applicant: OMNIVISION TECHNOLOGIES, INC., Santa Clara, CA (US)

(72) Inventors: Yin Qian, Milpitas, CA (US); Dyson H. Tai, San Jose, CA (US); Chia-Chun Miao, Santa Clara, CA (US); Chen-Wei Lu, San Jose, CA (US)

(21) Appl. No.: 14/957,464

(22) Filed: Dec. 2, 2015

(51) Int. Cl. H01L 27/146

(52) U.S. Cl. CPC H01L 27/14625; H01L 27/14643; H01L 27/1463; H01L 27/14636; H01L 27/14685

(57) ABSTRACT

An image sensor includes a plurality of photodiodes disposed in a semiconductor layer, a first isolation layer, and a dielectric filler. The dielectric filler is disposed in a trench in the first isolation layer, and the first isolation layer is disposed between the semiconductor layer and the dielectric filler. At least one additional isolation layer is disposed proximate to the first isolation layer, and a plurality of light channels in the at least one additional isolation layer extend through the at least one additional isolation layer to the dielectric filler. The plurality of light channels is disposed to direct light into the plurality of photodiodes.

### TECHNICAL FIELD

This disclosure relates generally to image sensors, and in particular but not exclusively, relates to the construction of light channels in image sensors.

### BACKGROUND INFORMATION

Image sensors have become ubiquitous. They are widely used in digital still cameras, cellular phones, security cameras, as well as, medical, automobile, and other applications. The technology used to manufacture image sensors has continued to advance at a great pace. For example, the demands of higher resolution and lower power consumption have encouraged the further miniaturization and integration of these devices.

Image sensor performance is directly related to the number of photons that reach (and are absorbed by) the photodiodes included in the image sensor. Often, photodiodes are buried beneath many layers of device architecture. Additional layers between the light source and the photodiode can result in scattering of photons incident on the image sensor, and prevent light form reaching the photodiodes. Accordingly, in image sensors with many layers of device architecture, a less than optimal number of photons may reach the photodiodes and result in degraded image quality; a problem that is further exacerbated by the ever shrinking cross sectional area of modern photodiodes.

One way to combat this issue involves forming additional structures on the surface of the image sensor to direct light into the photodiodes. However, the additional processing steps used to fabricate these structures may result in damage to the underlying electronic device or require many additional process steps.

### BRIEF DESCRIPTION OF THE DRAWINGS

Non-limiting and non-exhaustive examples of the invention are described with reference to the following figures, wherein like reference numerals refer to like parts throughout the various views unless otherwise specified.

FIG. 1 is a cross sectional illustration of one example of an image sensor with light channels, in accordance with the teachings of the present invention.

FIG. 2 is a block diagram illustrating one example of an imaging system including the image sensor with light channels of FIG. 1A, in accordance with the teachings of the present invention.

FIGS. 3A-3E show an example of a process for forming an image sensor with light channels, in accordance with the teachings of the present invention.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTION

Examples of an apparatus and method for an image sensor with light channels are described herein. In the following description, numerous specific details are set forth to provide a thorough understanding of the examples. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one example” or “one embodiment” means that a particular feature, structure, or characteristic described in connection with the example is included in at least one example of the present invention. Thus, the appearances of the phrases “in one example” or “in one embodiment” in various places throughout this specification are not necessarily all referring to the same example. Furthermore, the particular features, structures, or characteristics may be combined in any suitable manner in one or more examples.

Throughout this specification, several terms of art are used. These terms are to take on their ordinary meaning in the art from which they come, unless specifically defined herein or the context of their use would clearly suggest otherwise. It should be noted that element names and symbols are used interchangeably through this document (e.g., Si vs. silicon); however, both have identical meaning.

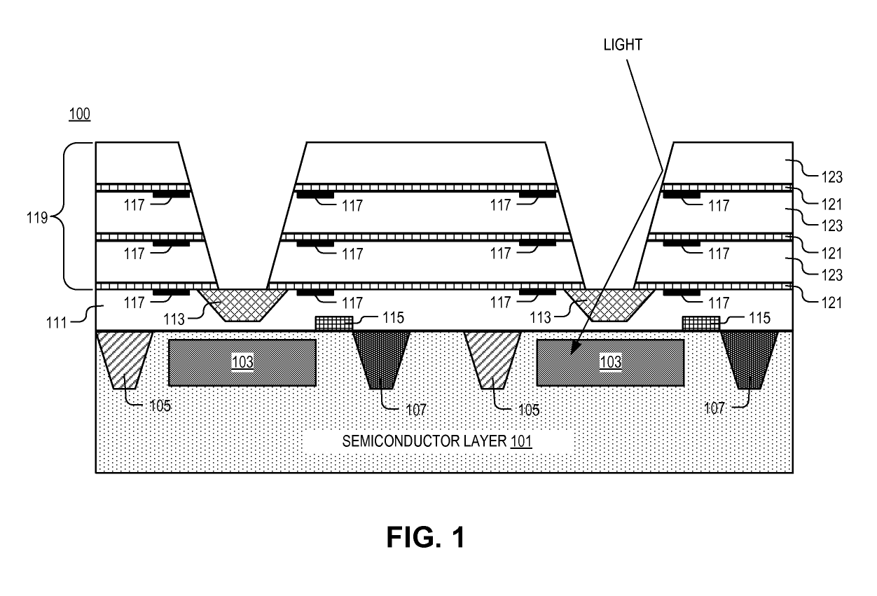

FIG. 1 is a cross sectional illustration of one example of an image sensor with light channels 100. Image sensor with light channels 100 includes: semiconductor layer 101, plurality of photodiodes 103, first isolation structure 111, dielectric filler 113, and at least one additional isolation layer 119. Also depicted in FIG. 1 are electrical isolation structures 105 and 107, transfer gate 115, metal interconnects 117, and individual dielectric layers 121 and 123 in at least one additional isolation layer 119. In the depicted example, plurality of photodiodes 103 is disposed in semiconductor layer 101. Dielectric filler 113 is disposed in a trench in first isolation layer 111, and first isolation layer 111 is disposed between semiconductor layer 101 and dielectric filler 113. Dielectric filler 113 is optically aligned with plurality of photodiodes 103. At least one additional isolation layer 119 is disposed on first isolation layer 111, such that first isolation layer 111 is disposed between at least one additional isolation layer 119 and semiconductor layer 101. In one example not depicted, dielectric filler 113 may contact both, semiconductor layer 101 and at least one additional isolation layer 119, such that first isolation layer 111 is not disposed between semiconductor layer 101 and dielectric filler 113. A plurality of light channels are etched in at least one additional isolation layer 119, where the plurality of light channels extend through at least one additional isolation layer 119 to dielectric filler 113. In one example, the plurality of light channels is disposed to direct light into plurality of photodiodes 103, and dielectric filler 113 is optically transparent to allow light to pass through dielectric filler 113 into plurality of photodiodes 103. In another or the same example, dielectric filler 113 includes a high-k dielectric material, and has a slower etch rate than at least one additional isolation layer 119.

In the depicted example, at least one additional isolation layer 119 includes a plurality of isolation layers (such as individual dielectric layers 121/123), as well as metal interconnects 117. However, in another example, at least one additional isolation layer 119 includes only a single isolation layer with no metal interconnects 117. In one example, at least one additional isolation layer 119 includes dielectric material, and the dielectric constant (k) of at least one additional isolation layer 119 is lower than a dielectric constant of dielectric filler 113.

The example in FIG. 1 shows that the plurality of light channels is optically aligned to direct light into plurality of photodiodes 103. In one example, cross sectional area of the plurality of light channels decreases in the direction of dielectric filler 113. In this configuration light enters the plurality of light channels, is reflected off of the sidewalls of at least one additional isolation layer 119, is transmitted through dielectric filler 113 and first isolation layer 111, and is absorbed by plurality of photodiodes 103. Thus, the light channels may help guide incident light from the surface of image sensor 100 into plurality of photodiodes 103, which may improve efficiency of the device.

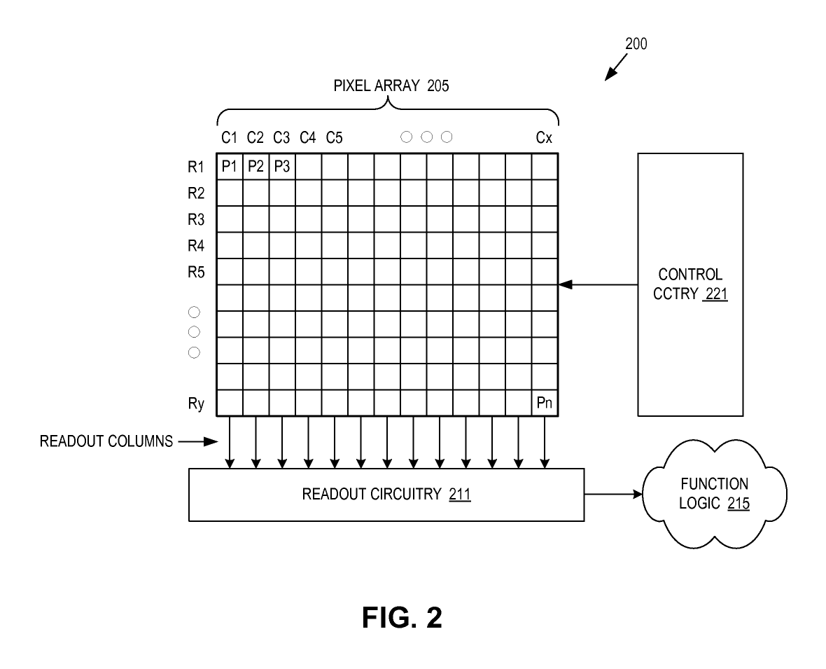

FIG. 2 is a block diagram illustrating one example of an imaging system including image sensor 100 (see FIG. 1). Imaging system 200 includes pixel array 205, control circuitry 221, readout circuitry 211, and function logic 215. In one example, image sensor 100 is included in an imaging system 200. In one example, pixel array 205 is a two-dimensional (2D) array of photodiodes, or image sensor pixels (e.g., pixels P1, P2 . . . , Pn). As illustrated, photodiodes are arranged into rows (e.g., rows R1 to Ry) and columns (e.g., column C1 to Cx) to acquire image data of a person, place, object, etc., which can then be used to render a 2D image of the person, place, object, etc.

In one example, after each image sensor photodiode/pixel in pixel array 205 has acquired its image data or image charge, the image data is readout by readout circuitry 211 and then transferred to function logic 215. Readout circuitry 211 may be coupled to readout image data from the plurality of photodiodes in pixel array 205. In various examples, readout circuitry 211 may include amplification circuitry, analog-to-digital (ADC) conversion circuitry, or otherwise. Function logic 215 may simply store the image data or even manipulate the image data by applying post image effects (e.g., crop, rotate, remove red eye, adjust brightness, adjust contrast, or otherwise). In one example, readout circuitry 211 may readout a row of image data at a time along readout column lines (illustrated) or may readout the image data using a variety of other techniques (not illustrated), such as a serial readout or a full parallel readout of all pixels simultaneously.

In one example, control circuitry 221 is coupled to pixel array 205 to control operation of the plurality of photodiodes in pixel array 205. Control circuitry 221 may be configured to control operation of the pixel array 205. For example, control circuitry 221 may generate a shutter signal for controlling image acquisition. In one example, the shutter signal is a global shutter signal for simultaneously enabling all pixels within pixel array 205 to simultaneously capture their respective image data during a single acquisition window. In another example, the shutter signal is a rolling shutter signal such that each row, column, or group of pixels is sequentially enabled during consecutive acquisition windows. In another example, image acquisition is synchronized with lighting effects such as a flash.

In one example, imaging system 200 may be included in a digital camera, cell phone, laptop computer, or the like. Additionally, imaging system 200 may be coupled to other pieces of hardware such as a processor, memory elements, output (USB port, wireless transmitter, HDMI port, etc.), lighting/flash, electrical input (keyboard, touch display, track pad, mouse, microphone, etc.), and/or display. Other pieces of hardware may deliver instructions to imaging system 200, extract image data from imaging system 200, or manipulate image data supplied by imaging system 200.

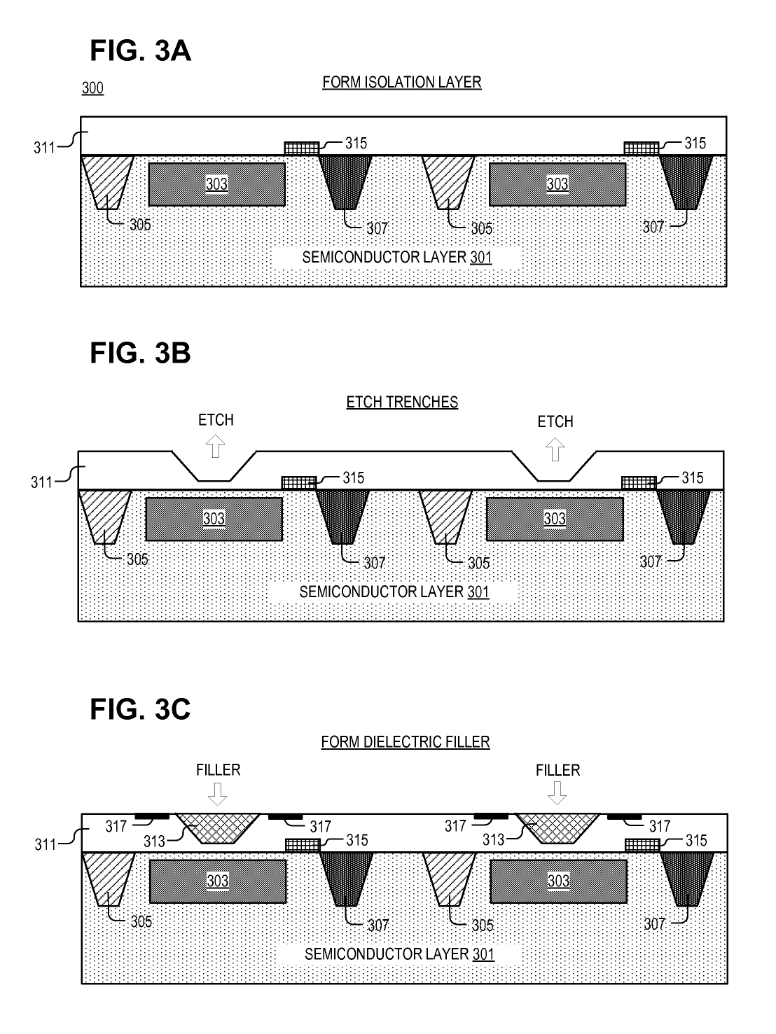

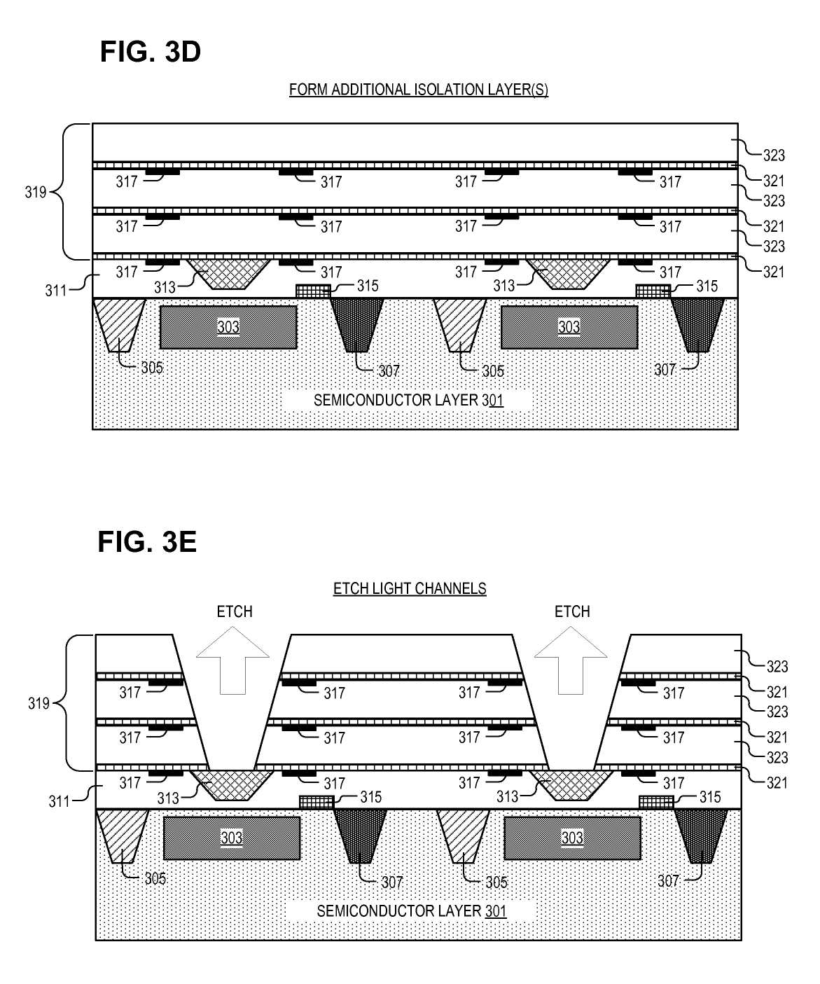

FIGS. 3A-3E show an example of a process 300 for forming an image sensor with light channels (e.g., image sensor with light channels 100). The order in which some or all of FIGS. 3A-3E appear in process 300 should not be deemed limiting. Rather, one of ordinary skill in the art having the benefit of the present disclosure will understand that some of the process may be executed in a variety of orders not illustrated, or even in parallel.

FIG. 3A illustrates forming first isolation layer 311 on semiconductor layer 301. In the depicted example, semiconductor layer 301 already contains plurality of photodiodes 303, electrical isolation structures 305/307, and transfer gate 315. It should be noted, that first isolation layer 311 may be formed through a wide variety of techniques including atomic layer deposition, chemical vapor deposition, or molecular beam epitaxy. In one example, electrical isolation structures 305 and 307 may be disposed in semiconductor layer 301 and surround at least in part individual photodiodes in plurality of photodiodes 303. This may prevent leakage current from flowing between individual photodiodes in plurality of photodiodes 303. Additionally, a floating diffusion may be housed within electrical isolation structure 307, therefore transfer gate 315 may be positioned to transfer image charge from plurality of photodiodes 303 into the floating diffusion in electrical isolation structure 307.

FIG. 3B illustrates etching trenches that extend partially into first isolation layer 311, where the trenches are disposed within first isolation layer 311 proximate to plurality of photodiodes 303. Etching is completed in preparation of forming dielectric filler 313. The etching process may either be wet or dry depending on the materials employed, desired geometry, and other considerations/limitations.

FIG. 3C illustrates forming dielectric filler 313 in first isolation layer 311, where first isolation layer 311 is disposed between dielectric filler 313 and semiconductor layer 301. Dielectric filler 313 may be deposited via a number of processes including chemical vapor deposition, molecular beam epitaxy or the like. In one example not shown, residual dielectric filler 313 is removed from the surface of first isolation layer 311 via chemical mechanical polishing or the like. In one example, dielectric filler 313 is optically transparent and has a higher dielectric constant (k) than first isolation layer 311.

Dielectric filler 313 and the trenches in first isolation layer 311, may take many shapes/forms. In the depicted example, the cross section of dielectric filler 313 is trapezoidal centered above plurality of photodiodes 303 within first isolation layer 311. Additionally, the largest edge of dielectric filler 313 is larger than the narrowest portion of the light trench. However in a different example, the widest section of dielectric filler 313 may be coextensive with the narrowest section of the light trench. In another example, the widest section of dielectric filler 313 may be coextensive with the diameter of a photodiode in plurality of photodiodes 303. This may prevent accidental etch damage to plurality of photodiodes 303. In one example, dielectric filler 313 may extend over both an individual photodiode in plurality of photodiodes 303, and transfer gate 315. This configuration may allow for dielectric filler 313 to prevent accidental etch damage to both the photodiodes and transfer gate 315. In another example, dielectric filler 313 may extend over an individual photodiode in plurality of photodiodes 303, transfer gate 315, and electrical isolation structures 105/107. In other words, in this example, the widest length of dielectric filler 313 is greater than or equal to the outside edges of electrical isolation structures 105/107.

FIG. 3D illustrates forming at least one additional isolation layer 319, where first isolation layer 311 is disposed between at least one additional isolation layer 319 and semiconductor layer 301. In one example, forming at least one additional isolation layer 319 includes forming multiple sequentially added individual isolation and or dielectric layers 321/323. In this example, layer 321 may be deposited followed by deposition of layer 323, and light channels may be etched in layers 321/323. This process may be repeated several times to form full size light channels. Etching following each layer deposition may allow for greater control of light channel geometry. Additionally, metal circuity 317 may be formed in the at least one additional isolation layer 319 along with other pieces of device architecture not shown in the example depicted in FIG. 3D.

FIG. 3F illustrates etching a plurality of light channels in at least one additional isolation layer 319, where the light channels extend through at least one additional isolation layer 319 to dielectric filler 313. In other words, the light channels extend from dielectric filler 313 through at least one additional isolation layer 319. In one example, etching the plurality of light channels in the at least one additional isolation layer 319 includes individually etching a plurality of light channels in each sequentially added additional isolation layer (e.g., layers 321/323). In the depicted example, dielectric filler 313 has a slower etch rate than at least one additional isolation layer 319. Further, the plurality of light channels in at least one additional isolation layer 319 is optically aligned with dielectric filler 313 and plurality of photodiodes 303, such that light can enter the light channels and pass through dielectric filler 313 and enter plurality of photodiodes 303. In one example, light channels may have sides that are substantially vertical, or alternatively, have sides with shallow angles (e.g., >20° from surface normal).

Although not depicted in FIGS. 3A-3E, in one example, light channels may be backfilled with a transparent material. In one example, the transparent material has a different index of refraction than at least one additional isolation layer 319. This may allow for the fabrication of additional layers of device architecture such as a color filter layer or a microlens layer on the surface of at least one additional isolation layer 319. In one example, the color filter layer includes red, green, and blue color filters which may be arranged into a Bayer pattern, EXR pattern, X-trans pattern, or the like. However, in a different or the same example, the color filter layer may include infrared filters, ultraviolet filters, or other light filters that isolate invisible portions of the EM spectrum.

In the same or a different example, a microlens layer is formed on the color filter layer. The microlens layer may be fabricated from a photo-active polymer that is patterned on the surface of the color filter layer. Once rectangular blocks of polymer are patterned on the surface of the color filter layer, the blocks may be melted (or reflowed) to form the dome-like structure characteristic of microlenses.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

1. An image sensor, the image sensor comprising:
a plurality of photodiodes disposed in a semiconductor layer;
a first isolation layer and a dielectric filler, wherein the dielectric filler is disposed in a trench in the first isolation layer, and wherein the first isolation layer is disposed between the semiconductor layer and the dielectric filler;
at least one additional isolation layer, wherein the first isolation layer is disposed between the at least one additional isolation layer and the semiconductor layer; and
a plurality of light channels in the at least one additional isolation layer wherein the plurality of light channels extend through the at least one additional isolation layer to the dielectric filler, and wherein the plurality of light channels is disposed to direct light into the plurality of photodiodes.

2. The image sensor of claim 1, wherein the dielectric filler is optically transparent, and wherein the dielectric filler is disposed to allow light to pass through the dielectric filler into the plurality of photodiodes.

3. The image sensor of claim 1, wherein the dielectric filler includes a high-k dielectric material, and wherein the dielectric filler has a slower etch rate than the at least one additional isolation layer.

4. The image sensor of claim 1, wherein the plurality of photodiodes, the dielectric filler, and the plurality of light channels are optically aligned to direct light into the plurality of photodiodes.

5. The image sensor of claim 1, wherein the at least one additional isolation layer includes a plurality of isolation layers.

6. The image sensor of claim 1, wherein a cross sectional area of the plurality of light channels decreases in the direction of the dielectric filler.

7. The image sensor of claim 1, wherein the at least one additional isolation layer includes dielectric material, and wherein a dielectric constant (k) of the at least one additional isolation layer is lower than a dielectric constant of the dielectric filler.

8. The image sensor of claim 1, further comprising control circuitry and readout circuity, wherein the control circuitry controls operation of the plurality of photodiodes and the readout circuitry reads out image charge from the plurality of photodiodes.

9. A photodetector, the photodetector comprising:
one or more photodiodes disposed in a semiconductor layer;
a first dielectric layer and a periodic second dielectric layer, wherein the first dielectric layer is disposed between the second dielectric layer and the one or more photodiodes, and wherein the second dielectric layer is optically aligned with the one or more photodiodes; and
a third dielectric layer, wherein the first dielectric layer and the periodic second dielectric layer are disposed between the third dielectric layer and the semiconductor layer, and wherein the third dielectric layer is punctuated with light channels extending from the second dielectric layer through the third dielectric layer.

10. The photodetector of claim 9, wherein the periodic second dielectric layer is disposed in trenches in the first dielectric layer.

11. The photodetector of claim 9, wherein third dielectric layer includes a plurality of individual dielectric layers and metal interconnects.

12. The photodetector of claim 9, wherein the second dielectric layer has a higher dielectric constant (k) than the first dielectric layer, and wherein the second dielectric layer is optically transparent.

13. The photodetector of claim 9, wherein the plurality of light channels in the third dielectric layer is optically aligned with the second dielectric layer and the one or more photodiodes, such that light can enter the light channels and pass through the second dielectric layer and enter the one or more photodiodes.

14. A method of image sensor fabrication, the method comprising:
forming a first isolation layer on a semiconductor layer, wherein the semiconductor layer contains a plurality of photodiodes;
forming a dielectric filler in the first isolation layer, wherein the first isolation layer is disposed between the dielectric filler and the semiconductor layer;
forming at least one additional isolation layer, wherein the first isolation layer is disposed between the at least one additional isolation layer and the semiconductor layer; and
etching a plurality of light channels in the at least one additional isolation layer, wherein the light channels extend through the at least one additional isolation layer to the dielectric filler.

15. The method of claim 14, wherein forming the dielectric filler in the first isolation layer includes:
etching a plurality of trenches in the first isolation layer, wherein the plurality of trenches are disposed proximate to the plurality of photodiodes; and
depositing the dielectric filler in the plurality of trenches.

16. The method of claim 15, further comprising removing residual dielectric filler from the surface of the first isolation layer.

17. The method of claim 14, wherein forming the at least one additional isolation layer includes forming multiple sequentially added additional isolation layers.

18. The method of claim 17, wherein etching the plurality of light channels in the at least one additional isolation layer includes individually etching a plurality of light channels in each sequentially added additional isolation layer.

19. The method of claim 14, further comprising forming metal circuitry in the at least one additional isolation layer.

20. The method of claim 14, wherein the dielectric filler has a slower etch rate than the at least one additional isolation layer.
